(19) United States
(12) Patent Application Publication
(10) Pub. No.: US 2014/0021426 A1
(43) Pub. Date: Jan. 23, 2014

(54) MAGNETIC DEVICE AND METHOD OF MANUFACTURING THE SAME

(71) Applicants: Yun-jae LEE, Seoul (KR); Woo-jin KIM, Yongin-si (KR); Joon-myoung LEE, Suwon-si (KR)

(72) Inventors: Yun-jae LEE, Seoul (KR); Woo-jin KIM, Yongin-si (KR); Joon-myoung LEE, Suwon-si (KR)

(21) Appl. No.: 13/927,090

(22) Filed: Jun. 25, 2013

(30) Foreign Application Priority Data
Jul. 17, 2012 (KR) 10-2012-0077922

(51) Int. Cl. H01L 43/02

(52) U.S. Cl. CPC H01L 43/02
USPC 257/1

(57) ABSTRACT

A magnetic device comprises a memory cell comprising a magnetic resistance device and lower and upper electrodes with the magnetic resistance device interposed therebetween to apply current to the magnetic resistance device. The magnetic resistance device includes: a buffer layer for controlling a crystalline axis for inducing perpendicular magnetic anisotropy (PMA) in the magnetic resistance device, the buffer layer being in contact with the lower electrode; a seed layer being in contact with the buffer layer and being oriented to a hexagonal close-packed lattice (HCP) (0001) crystal plane; and a perpendicularly magnetized pinned layer being in contact with the seed layer and having an L1₁ type ordered structure.

### CROSS-REFERENCE TO RELATED APPLICATIONS

This application claims the benefit of Korean Patent Application No. 10-2012-0077922, filed on Jul. 17, 2012, in the Korean Intellectual Property Office, the disclosure of which is incorporated herein in its entirety by reference.

### BACKGROUND

The inventive concept relates to a magnetic device and a method of manufacturing the magnetic device, and, more particularly, to a magnetic device including a magnetic layer with perpendicular magnetic anisotropy (PMA) and a method of manufacturing the magnetic device.

Research into electronic devices using magnetic resistance characteristics of magnetic tunnel junctions (MTJs) is actively being performed. In particular, due to the miniaturization of an MTJ cell of a highly-integrated magnetic random access memory (MRAM), spin transfer torque (STT)-MRAM that stores information based on a physical phenomenon of STT by inducing magnetization reversal obtained by applying a current to an MTJ cell is receiving attention. A highly-integrated STT-MRAM requires a minute-sized MTJ structure having a magnetic layer with a sufficient PMA.

### SUMMARY

The inventive concept provides a magnetic device that substantially reduces a switching malfunction due to a stray field and secures a stable switching characteristic and high reading margin by a high spin polarization rate.

The inventive concept also provides a method of manufacturing a magnetic device having a stack structure that generates high perpendicular magnetic anisotropy (PMA) while matching well with an electrode material and provides a stable switching characteristic by a high spin polarization rate.

According to an aspect of the inventive concept, a magnetic device includes a memory cell, the memory cell including a magnetic resistance device and lower and upper electrodes with the magnetic resistance device interposed therebetween to apply current to the magnetic resistance device.

The magnetic resistance device includes: a buffer layer for controlling a crystalline axis for inducing perpendicular magnetic anisotropy (PMA) in the magnetic resistance device, the buffer layer being in contact with the lower electrode; a seed layer being in contact with the buffer layer and being oriented to have a hexagonal close-packed lattice (HCP) (0001) crystal plane; and a perpendicularly magnetized pinned layer being in contact with the seed layer and having an L1₁ type ordered structure.

According to another aspect of the inventive concept, a magnetic device includes an electrode; a buffer layer formed on the electrode; a seed layer formed on the buffer layer; a first magnetized layer formed on the seed layer; a first tunnel barrier formed on the first magnetized layer; a second magnetized layer formed on the first tunnel barrier; and a third magnetized layer formed on the second magnetized layer and having a synthetic antiferromagnetic coupling (SAF) structure.

According to another aspect of the inventive concept, a method of manufacturing a magnetic device includes: forming a buffer layer having an HCP (0001) crystal structure or amorphous structure on an electrode; forming a seed layer having an HCP (0001) crystal structure on the buffer layer; and forming a perpendicularly magnetized pinned layer on the seed layer.

According to another aspect of the inventive concept, a method of manufacturing a magnetic device includes: forming an electrode including a TiN film; forming a buffer layer being in contact with an upper surface of the TiN layer and including an HCP (0001) crystal structure or an amorphous structure; forming a seed layer including a Ru film contacting with an upper surface of the buffer layer; forming a magnetized pinned layer having an L1₁ type ordered structure on the Ru film; and forming a CoFeB polarization enhanced layer being in contact with an upper surface of the magnetized pinned layer and being magnetized in a direction perpendicular to the upper surface.

A magnetic device according to the inventive concept may prevent a switching malfunction due to a stray field and may provide a stable switching characteristic by a high spin polarization rate.

### BRIEF DESCRIPTION OF THE DRAWINGS

Exemplary embodiments of the inventive concept will be more clearly understood from the following detailed description taken in conjunction with the accompanying drawings in which:

FIG. 1 is a diagram illustrating a schematic configuration of a magnetic device according to an embodiment of the inventive concept;

FIG. 2 is a diagram illustrating a magnetic tunnel junction (MTJ) structure including a perpendicularly magnetized pinned layer having a synthetic antiferromagnetic coupling (SAF) structure;

FIG. 3 is a graph for describing an example in which a shift in a coercive field Hc occurs in a free layer of an MTJ structure;

FIG. 4 is a cross-sectional view illustrating a magnetic device according to an embodiment of the inventive concept;

FIG. 5A is a partial perspective view showing an arrangement of a plurality of atoms in a buffer layer of a magnetic device according to some embodiments of the inventive concept;

FIG. 5B is a partial plan view showing an arrangement of the plurality of atoms 114A in a buffer layer of a magnetic device according to some embodiments of the inventive concept;

FIG. 6A is a partial perspective view showing an exemplary arrangement of a plurality of atoms in a lower magnetized pinned layer of a magnetic device according to some embodiments of the inventive concept;

FIG. 6B is a diagram showing a crystal structure of a lower magnetized pinned layer of a magnetic device according to some embodiments of the inventive concept;

FIG. 7 is a graph for describing an Hc distribution of a first upper magnetized pinned layer, an Hc distribution of a second upper magnetized pinned layer, and an Hc distribution of a lower magnetized pinned layer in a magnetic device according to some embodiments of the inventive concept;

FIG. 8 is a cross-sectional view illustrating a magnetic device according to another embodiment of the inventive concept;

FIG. 9 is a cross-sectional view illustrating a magnetic device according to another embodiment of the inventive concept;

FIG. 10 is a flowchart illustrating, according to a process sequence, a method of manufacturing a magnetic device, according to an embodiment of the inventive concept;

FIGS. 11A through 11K are cross-sectional views illustrating, according to a process sequence, a method of manufacturing a magnetic device, according to an embodiment of the inventive concept;

FIG. 12 is a graph illustrating a magnetization hysteresis (M-H) loop of a magnetic device according to embodiments of the inventive concept;

FIG. 13 is a graph illustrating another M-H loop for comparison;

FIG. 14 is a graph illustrating magnetic moment characteristics according to a magnetic field applied from the outside in a magnetic device according to an embodiment of the inventive concept;

FIG. 15 is a block diagram of an electronic system including a magnetic device according to an embodiment of the inventive concept;

FIG. 16 is a block diagram of an information processing system including a magnetic device according to an embodiment of the inventive concept; and

FIG. 17 is a block diagram of a memory card including a magnetic device according to an embodiment of the inventive concept.

### DETAILED DESCRIPTION OF THE EMBODIMENTS

Expressions such as “at least one of,” when preceding a list of elements, modify the entire list of elements and do not modify the individual elements of the list.

Example embodiments of the inventive concept will be described more fully with reference to the accompanying drawings. Like reference numerals in the drawings refer to like elements, and redundant descriptions thereof are omitted.

Reference will now be made in detail to exemplary embodiments, and examples of which are illustrated in the accompanying drawings. However, exemplary embodiments are not limited to the embodiments illustrated hereinafter, and the embodiments herein are rather introduced to provide easy and complete understanding of the scope and spirit of exemplary embodiments.

It will be understood that, although the terms ‘first’, ‘second’, ‘third’, etc. may be used herein to describe various elements, components, regions, layers and/or sections, these elements, components, regions, layers and/or sections should not be limited by these terms. These terms refer to a particular order, rank, or superiority and are only used to distinguish one element, component, region, layer or section from another element, component, region, layer or section. Thus, a first element, component, region, layer or section discussed below could be termed a second element, component, region, layer or section without departing from the teachings of the example embodiment. For example, a first element may be referred to as a second element, and similarly, a second element may be referred to as a first element without departing from the scope of protection of the inventive concept.

Unless otherwise defined, all terms (including technical and scientific terms) used herein have the same meaning as commonly understood by one of ordinary skill in the art to which exemplary embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

If any embodiment is implemented otherwise, a particular process may be performed differently from the described order. For example, two continuously-described processes may be substantially simultaneously performed or in an opposite order to the described order.

In the drawings, for example, illustrated shapes may be deformed according to fabrication technology and/or tolerances. Therefore, the exemplary embodiments of the present invention are not limited to certain shapes illustrated in the present specification, and may include modifications of shapes caused in fabrication processes.

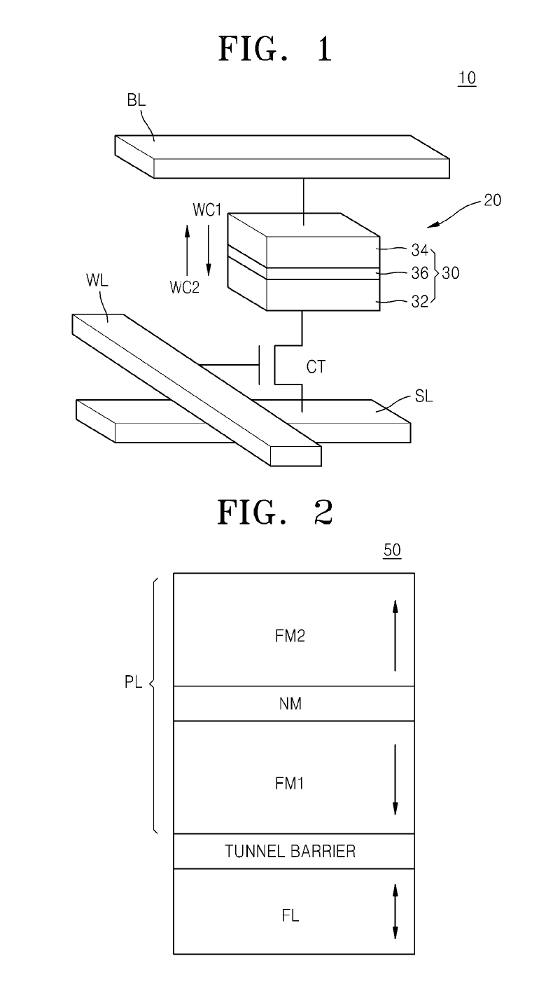

FIG. 1 is a diagram illustrating a schematic configuration of a magnetic device 10 according to an embodiment of the inventive concept. A memory cell 20 of the magnetic device 10 formed of a spin transfer torque magnetic random access memory (STT-MRAM) is illustrated in FIG. 1.

The memory cell 20 may include a magnetic tunnel junction (MTJ) structure 30 and a cell transistor CT. A gate of the cell transistor CT is connected to a word line WL, and one electrode of the cell transistor CT is connected to a bit line BL through the MTJ structure 30. The other electrode of the cell transistor CT is connected to a source line SL.

The MTJ structure 30 includes a pinned layer (or a reference layer) 32, a free layer 34, and a tunnel barrier interposed between the pinned layer 32 and the free layer 34. The pinned layer 32 has a magnetization easy axis in a direction perpendicular to a surface of the pinned layer 32, and a magnetization direction of the pinned layer 32 is fixed. The free layer 34 has a magnetization easy axis in a direction perpendicular to a surface of the free layer 34, and a magnetization direction of the free layer 34 changes by passing a spin-polarized current.

A resistance value of the MTJ structure 30 is changed according to the magnetization direction of the free layer 34. When the magnetization direction of the free layer 34 and the magnetization direction of the pinned layer 32 are parallel to each other, the MTJ structure 30 has a low resistance value and may store data ‘0’. When the magnetization direction of the free layer 34 and the magnetization direction of the pinned layer 32 are antiparallel to each other, the MTJ structure 30 has a high resistance value and may store data ‘1’. The position of the pinned layer 32 and the position of the free layer 34 are not limited to an example of FIG. 1, and may be exchanged with each other.

In the magnetic device 10 illustrated in FIG. 1, for a write operation of the STT-MRAM, the cell transistor CT is turned on by applying a logic high voltage level to the word line WL, and a write current WC1 or WC2 is applied between the bit line BL and the source line SL. In this case, the magnetization direction of the free layer 34 may be determined according to a direction of the write current WC1 or WC2. For example, when the write current WC1 is applied, free electrons having the same spin direction as the pinned layer 32 apply torque to the free layer 34, and thus, the free layer 34 may be magnetized in the same direction as the pinned layer 32. In addition, when the write current WC2 is applied, electrons having the opposite spin direction to the pinned layer 32 return to the free layer 34 and apply torque to the free layer 34, and thus, the free layer 34 may be magnetized in the opposite direction to the pinned layer 32. In this manner, in the MTJ structure 30, the magnetization direction of the free layer 34 may be changed by STT.

In the magnetic device 10 illustrated in FIG. 1, for a read operation of the STT-MRAM, the cell transistor CT is turned on by applying a logic high voltage level to the word line WL and data stored in the MTJ structure 30 may be determined by applying a read current from the bit line BL toward the source line SL. In this case, since the intensity of the read current is much smaller than that of the write current WC1 or WC2, the magnetization direction of the free layer 34 is not changed by the read current.

In order to commercialize a high integrated and high speed STT-MRAM, it is required to secure a stable switching characteristic and a high reading margin in the free layer 34 of the MTJ structure 30. In a vertical MTJ structure, the pinned layer 32 may be formed by using a vertical synthetic antiferromagnetic coupling (SAF) structure.

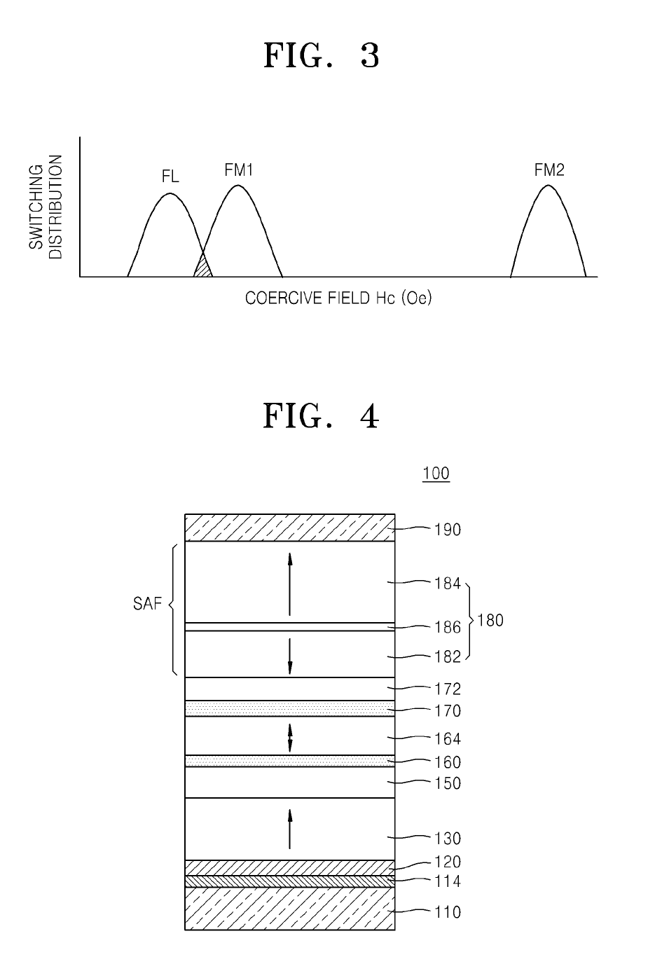

FIG. 2 is a diagram illustrating an MTJ structure 50 including a perpendicularly magnetized pinned layer PL having an SAF structure.

The perpendicularly magnetized pinned layer PL having an SAF structure includes two ferromagnetic layers FM1 and FM2 separated from each other by a thin non-magnetic layer NM. A non-ferromagnetic coupling characteristic occurs in the SAF structure due to a Ruderman-Kittel-Kasuya-Yosida (RKKY) interaction by the thin non-magnetic layer NM inserted between the two ferromagnetic layers FM1 and FM2. By a non-ferromagnetic coupling interacting between the two ferromagnetic layers FM1 and FM2, magnetic domains of each ferromagnetic layer are aligned in opposite directions to each other, thereby minimizing the total amount of magnetization of the SAF structure and reducing a stray field.

When a magnetic field applied to a free layer FL from the outside gradually increases and then reaches a critical value of magnetization reversal, an electrical resistance value is instantaneously changed due to the magnetization reversal or switching. In this case, the magnetic field is represented as a coercive field (Hc), i.e., a switching field. However, a stray field may not be cancelled and may remain in the SAF structure of the perpendicularly magnetized pinned layer PL. If a magnetic filed due to the stray field is formed, it may influence a magnetization process of the free layer FL. The stray field of the pinned layer PL may induce an Hc shift in the free layer FL.

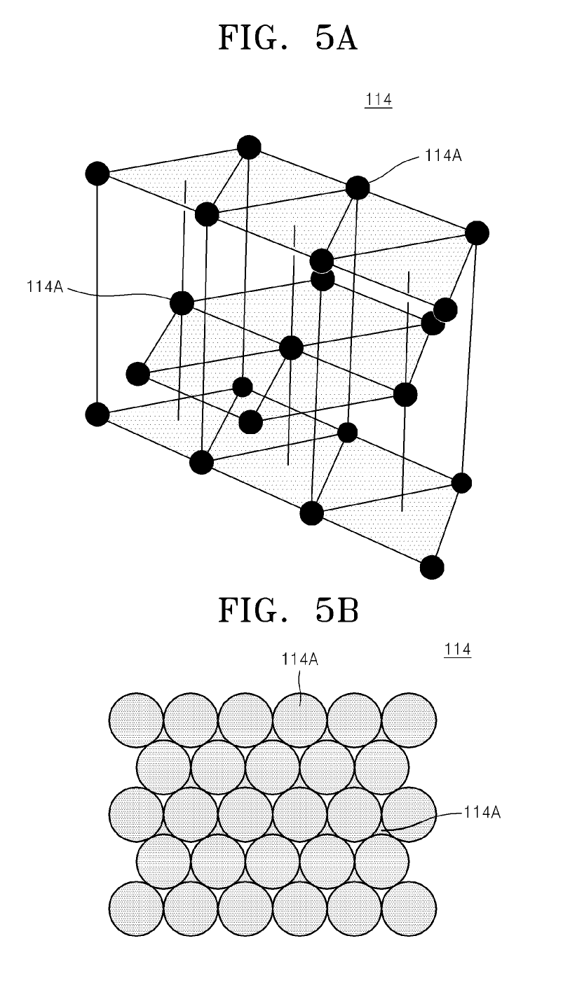

FIG. 3 is a graph for describing an example in which in an MTJ structure including a pinned layer having an SAF structure, such as the MTJ structure 50 illustrated in FIG. 2, in which an Hc shift occurs in a free layer FL.

A stray field of the pinned layer PL may induce a shift in the Hc distribution of the free layer FL, thereby causing distribution of a switching voltage. Alternatively, as illustrated in FIG. 3, the Hc distribution of the free layer FL may overlap with the Hc distribution of one of two ferromagnetic layers FM1 and FM2 constituting the pinned layer PL, and thus, a switching malfunction may be caused.

Embodiments of the inventive concept each provide a magnetic device having an MTJ structure, which may suppress an Hc shift of the free layer FL by cancelling a stray field from the pinned layer PL and may improve a switching characteristic and the overall reliability of the magnetic device.

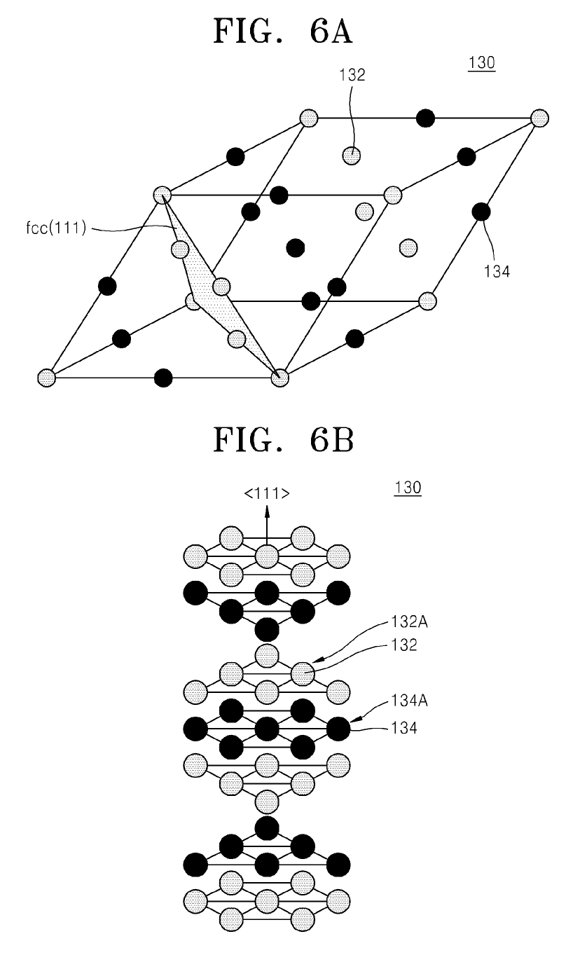

FIG. 4 is a cross-sectional view illustrating a magnetic device 100 according to an embodiment of the inventive concept.

The magnetic device 100 includes an electrode 110, a buffer layer 114 formed on the electrode 110, a seed layer 120 formed on the buffer layer 114, and a lower magnetized pinned layer 130 formed on the seed layer 120.

The buffer layer 114 is interposed between the electrode 110 and the seed layer 120, and thus, matches a crystal structure of the electrode 110 to a crystal structure of the seed layer 120 and controls a crystalline axis of the seed layer 120 so that a vertical orientation property of the seed layer 120 increases.

The electrode 110 may be formed of a metal or a metal nitride. For example, the electrode 110 may be formed of TiN.

The electrode 110 may be formed by using a chemical vapor deposition (CVD) process, a physical vapor deposition (PVD) process, an atomic layer deposition (ALD) process, or a reactive pulsed laser deposition (PLD) process.

The lower magnetized pinned layer 130 provides a stable switching characteristic by cancelling a stray field of an upper magnetized pinned layer 180 having an SAF structure. The lower magnetized pinned layer 130 is formed of a superlattice with long-range order, which has high perpendicular magnetic anisotropy (PMA).

When forming the lower magnetized pinned layer 130 using a superlattice with long-range order, the buffer layer 114 and the seed layer 120, which are arranged between the electrode 110 and the lower magnetized pinned layer 130, play an important role in achieving a high PMA. In an MRAM device, the electrode 110 may be connected to a transistor. Accordingly, matching between a material forming the electrode 110 and a material forming the lower magnetized pinned layer 130 may be desirable to secure a sufficient magnetization characteristic in the lower magnetized pinned layer 130. In some embodiments of the inventive concept, in order to match a material forming the electrode 110 to a material forming the lower magnetized pinned layer 130, the buffer layer 114 for controlling the crystalline axis of the seed layer 120, and the seed layer 120 for forming the lower magnetized pinned layer 130 by using a superlattice with long-range order, are sequentially formed between the electrode 110 and the lower magnetized pinned layer 130.

The electrode 110 may be formed of a TiN film having a relatively low nitrogen content to implement a low interconnection resistance. For example, the electrode 110 may be formed of a TiN film in which a nitrogen (N) atomic rate is lower than a titanium (Ti) atomic rate.

In some embodiments, the electrode 110, the buffer layer 114, and the seed layer 120 may have the same crystal structure. For example, the electrode 110, the buffer layer 114, and the seed layer 120 may each have a hexagonal close-packed lattice (HCP) crystal structure.

In some other embodiments, the buffer layer 114 and the seed layer 120 may have the same crystal structure regardless of a crystal structure of the electrode 110. For example, the buffer layer 114 and the seed layer 120 may have an HCP (0001) crystal structure. To this end, the buffer layer 114 may include a thin film formed of Ti, Zr, Hf, Y, Sc, or Mg. In addition, the seed layer 120 may include a Ru layer.

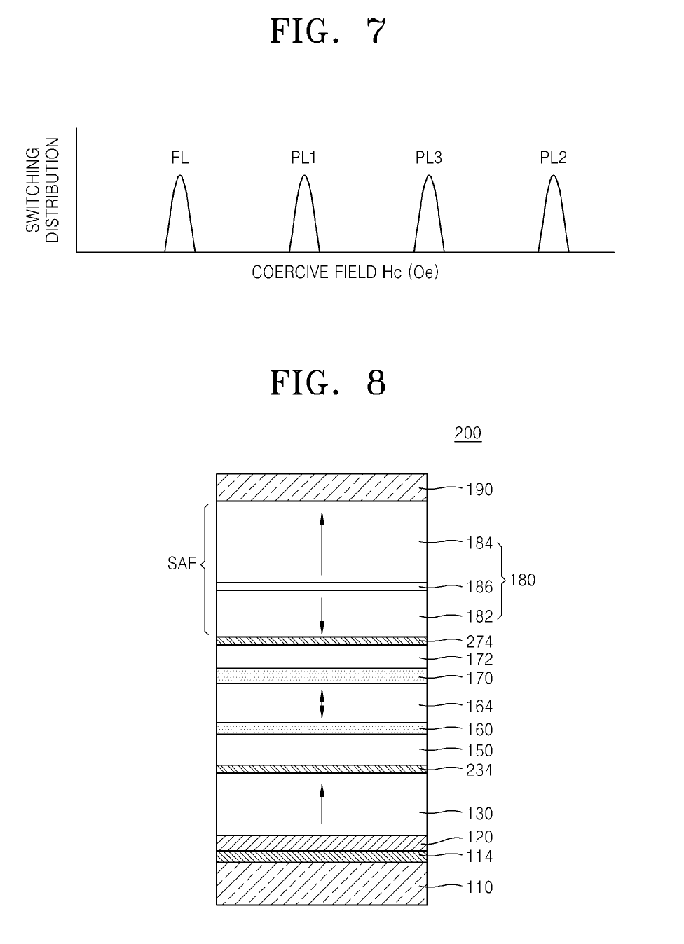

FIG. 5A is a partial perspective view showing an arrangement of a plurality of atoms 114A in the buffer layer 114 having an HCP (0001) crystal structure. FIG. 5B is a partial plan view showing an arrangement of the plurality of atoms 114A in the buffer layer 114 having an HCP (0001) crystal structure.

The plurality of atoms 114A forming the buffer layer 114 are aggregated densely with close-packed structure in a (0001) plane that is a close-packed plane.

Referring back to FIG. 4, the seed layer 120 may include a plurality of metal atoms arranged in the same manner as the arrangement of the plurality of atoms 114A illustrated in FIGS. 5A and 5B.

In some other embodiments, the buffer layer 114 illustrated in FIG. 4 may be formed of an amorphous material and the seed layer 120 may have an HCP (0001) crystal structure. The buffer layer 114 may be formed of an amorphous alloy material including cobalt (Co). For example, the buffer layer 114 may include a thin film formed of CoZr, CoHf, or CoFeBTa.

The buffer layer 114 and the seed layer 120 may each be formed by using a CVD process, a PVD process, an ALD process, or a reactive PLD process. In some embodiments, the buffer layer 114 and the seed layer 120 may each be formed by using a DC magnetron sputtering process using krypton (Kr) as a sputtering gas.

The buffer layer 114 may have a thickness in the range of about 0.1 nm to about 1.5 nm. The seed layer 120 may have a thickness in the range of about 1 nm to about 10 nm. The thickness of the seed layer 120 may be larger than that of the buffer layer 114.

The lower magnetized pinned layer 130 has a magnetization easy axis in a direction substantially perpendicular to a surface of the seed layer 120. In the lower magnetized pinned layer 130, a magnetization direction thereof is not changed. Although in FIG. 4, the magnetization direction of the lower magnetized pinned layer 130 is illustrated as being arranged opposite the direction of the electrode 110, that is, in a direction towards the upper magnetized pinned layer 180, the inventive concept is not limited thereto. For example, the magnetization direction of the lower magnetized pinned layer 130 may be arranged towards the electrode 110.

In some embodiments, the lower magnetized pinned layer 130 may have an L1₁ type ordered structure. Since the seed layer 120 has an HCP (0001) structure, a growth in a (111) plane may be faster when forming the lower magnetized pinned layer 130 on the seed layer 120, and the lower magnetized pinned layer 130 that is formed of a superlattice with long-range order, which has an L1₁ type ordered structure, may be formed on the seed layer 120 (where L1₁ is named according to a Strukturbericht designation).

The L1₁ type ordered structure has a quasistable rhombohedral phase and has a magnetization easy axis in a direction substantially perpendicular to a surface of the lower magnetized pinned layer 130. The lower magnetized pinned layer 130 having the L1₁ type ordered structure includes face-centered-cubic (fcc) layers in which component elements are deposited according to a <111> direction.

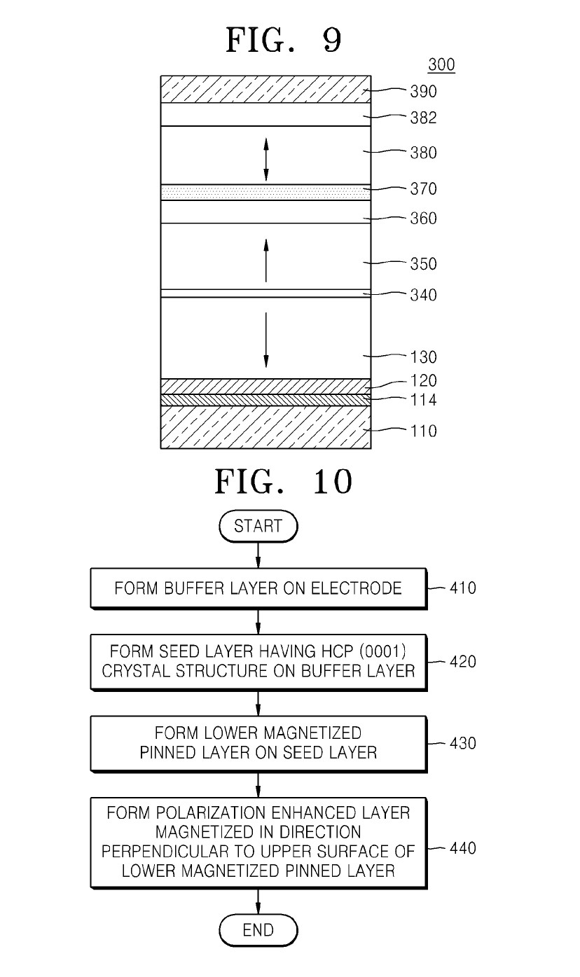

FIG. 6A is a partial perspective view showing an exemplary arrangement of a plurality of atoms in the lower magnetized pinned layer 130 having the L1₁ type ordered structure, and FIG. 6B is a diagram showing a crystal structure of the lower magnetized pinned layer 130 having the L1₁ type ordered structure.

The lower magnetized pinned layer 130 may be formed of a substantially perpendicularly magnetized pinned layer in which a first layer 132A, including first atoms 132, and a second layer 134A, including second atoms 134, are alternately formed. In some embodiments, the lower magnetized pinned layer 130 may be formed of a Co-based perpendicularly magnetized pinned layer. For example, each of the first atoms 132 of the lower magnetized pinned layer 130 is Co, and each of the second atoms 134 of the lower magnetized pinned layer 130 is Pt or Pd. In the lower magnetized pinned layer 130, the first layer 132A and the second layer 134A are each oriented to an fcc (111) plane.

In some embodiments, the lower magnetized pinned layer 130 has a structure of [Co/Pt]×n (where n is the number of repeated structures) in which a Co film having a thickness in the range of about 1 Å to about 2 Å and a Pt film having a thickness in the range of about 1 Åto about 2 Å are repeatedly alternately stacked. In some embodiments, the lower magnetized pinned layer 130 has a structure of [Co/Pd]×n (where n is the number of repeats) in which a Co film having a thickness in the range of about 1 Å to about 2 Å and a Pd film having a thickness in the range of about 1 Å to about 2 Å are alternately stacked multiple times.

The lower magnetized pinned layer 130 may be formed by using a thin film epitaxial growth process through a solid state epitaxial growth. For example, the lower magnetized pinned layer 130 may be formed by using a molecular beam epitaxy (MBE) process or a metal organic CVD (MOCVD) process.

The lower magnetized pinned layer 130 may be formed under a relatively low process temperature in the range of about 200° C. to about 400° C. For example, the lower magnetized pinned layer 130 may be formed under about 300° C. In this manner, because the lower magnetized pinned layer 130 may be formed under a relatively low process temperature, the lower magnetized pinned layer 130 may be easily formed without negatively influencing another portion of the magnetic device 100 through a high temperature process. In addition, in the case of a magnetic tunneling junction (MTJ) structure including a magnetic layer having a perpendicular magnetic characteristic, the perpendicular magnetic characteristic of the magnetic layer has to be maintained without degradation also under a succeeding high temperature annealing process. A superlattice layer forming the lower magnetized pinned layer 130, which has the L1₁ structure, may maintain a stable perpendicular magnetic characteristic also under a succeeding annealing process temperature of about 370° C. and thus may retain an excellent perpendicular magnetic characteristic.

The lower magnetized pinned layer 130 may be formed by using an MBE process, a magnetron sputtering process, or an ultra-high vacuum (UHV) sputtering process. The lower magnetized pinned layer 130 may have a thickness in the range of about 20 Å to about 30 Å.

Since the lower magnetized pinned layer 130 has excellent perpendicular anisotropy and may be formed under a relatively low temperature, the lower magnetized pinned layer 130 may be reliably applied to a magnetic device.

Referring back to FIG. 4, a (0001) close-packed plane of the seed layer 120 has a matching property with respect to an fcc (111) close-packed plane of the lower magnetized pinned layer 130 having the L1₁ structure. Accordingly, when forming an L1₁ type superlattice layer on the seed layer 120 in a state in which a vertical orientation property of the seed layer 120 has been increased due to the buffer layer 114 by forming the seed layer 120 on the buffer layer 114, the L1₁ type superlattice layer includes a long-range order structure along an out-of-plane axis of grains of elements constituting the seed layer 120 and thus has high perpendicular anisotropy. In addition, coercivity conspicuously increases, and thus, the reliability of the magnetic device may be improved and a driving power of the magnetic device may be reduced.

A first polarization enhanced layer 150 is formed on the lower magnetized pinned layer 130 to increase the spin polarization of the lower magnetized pinned layer 130. The first polarization enhanced layer 150 may be a magnetic layer formed of Co, Fe, and B (hereinafter, referred to as “CoFeB magnetic layer.”). The CoFeB magnetic layer basically has in-plane magnetic anisotropy. However, when forming the CoFeB magnetic layer to contact the lower magnetized pinned layer 130 formed of the L1₁ type superlattice layer, the CoFeB magnetic layer may be substantially vertically oriented to a thickness of at least 17 Å. Accordingly, the first polarization enhanced layer 150 that is formed on the lower magnetized pinned layer 130 may be formed of a vertically-oriented CoFeB magnetic layer, and may provide high spin polarization by a combination of the lower magnetized pinned layer 130 and the first polarization enhanced layer 150. The magnetization direction of the first polarization enhanced layer 150 may be substantially the same as that of the lower magnetized pinned layer 130. The first polarization enhanced layer 150 may have a thickness in the range of about 10 Å to about 20 Å.

A first tunnel barrier 160 is formed on the first polarization enhanced layer 150, and a magnetized free layer 164 is formed on the first tunnel barrier 160. In addition, a second tunnel barrier 170 may be formed on the magnetized free layer 164, and an upper magnetized pinned layer 180 may be formed on the second tunnel barrier 170.

The first tunnel barrier 160 and the second tunnel barrier 170 may each include a non-magnetic material. In some embodiments, the first tunnel barrier 160 and the second tunnel barrier 170 may each be formed of an oxide of any one material chosen from Mg, Ti, Al, MgZn, and MgB. In some other embodiments, the first tunnel barrier 160 and the second tunnel barrier 170 may each be formed of a Ti nitride or a vanadium (V) nitride. In some embodiments, the first tunnel barrier 160 and the second tunnel barrier 170 may each be formed of a single layer. In some other embodiments, the first tunnel barrier 160 and the second tunnel barrier 170 may each be formed of multiple layers including sequentially stacked layers. For example, the first tunnel barrier 160 and the second tunnel barrier 170 may each have a multiple layer structure chosen from Mg/MgO, MgO/Mg, and Mg/MgO/Mg. In some embodiments, the second tunnel barrier 170 may have a larger thickness than the first tunnel barrier 160.

The magnetic device 100 illustrated in FIG. 4 provides a dual MTJ structure including the first and second tunnel barriers 160 and 170. When a current is supplied through the dual MTJ structure including the first and second tunnel barriers 160 and 170, the magnetized free layer 164 switches the magnetization of the free layer, e.g., between stable magnetic states. The magnetic device 100 may provide an improved performance in a highly integrated magnetic memory device by having the dual MTJ structure.

A second polarization enhanced layer 172 is interposed between the second tunnel barrier 170 and the upper magnetized pinned layer 180.

The second polarization enhanced layer 172 may include a ferromagnetic material chosen from among Co, Fe, and Ni. The second polarization enhanced layer 172 may have a high spin polarization rate and a low damping constant. To this end, the second polarization enhanced layer 172 may further include a non-magnetic material chosen from among B, Zn, Ru, Ag, Au, Cu, C, and N. In some embodiments, the second polarization enhanced layer 172 may be formed of a CoFeB magnetic layer. The second polarization enhanced layer 172 may have a thickness in the range of about 10 Å to about 20 Å.

The upper magnetized pinned layer 180 includes a first upper magnetized pinned layer 182, a second upper magnetized pinned layer 184, and an interchange combination film 186 interposed between the first upper magnetized pinned layer 182 and the second upper magnetized pinned layer 184.

The first upper magnetized pinned layer 182 has a magnetic moment antiparallel to a magnetic moment of the lower magnetized pinned layer 130. The second upper magnetized pinned layer 184 has a magnetic moment antiparallel to a magnetic moment of the first upper magnetized pinned layer 182.

The upper magnetized pinned layer 180 may have an SAF structure as described with respect to the perpendicularly magnetized pinned layer PL with reference to FIG. 2. In this case, the first upper magnetized pinned layer 182 and the second upper magnetized pinned layer 184 may correspond to the ferromagnetic layer FM1 and the ferromagnetic layer FM2, respectively. The interchange combination film 186 may correspond to the thin non-magnetic layer NM inserted between the two ferromagnetic layers FM1 and FM2.

The second polarization enhanced layer 172 may increase the spin polarization of the first upper magnetized pinned layer 182. A magnetization direction of the second polarization enhanced layer 172 may be the same as that of the first upper magnetized pinned layer 182.

A capping layer 190 may be formed on the upper magnetized pinned layer 180. The capping layer 190 may be chosen from among Ta, Al, Cu, Au, Ag, Ti, TaN, and TiN.

In the magnetic device 100 illustrated in FIG. 4, a resistance value of the magnetic device 100 may be changed according to the direction of electrons flowing through the dual MTJ structure, and data may be stored in a memory cell including the magnetic device 100 by using a difference in the resistance value.

In the magnetic device 100 illustrated in FIG. 4, by optimizing Hc of the lower magnetized pinned layer 130 so that Hc of the lower magnetized pinned layer 130 is in the range between Hc of the first upper magnetized pinned layer 182 and Hc of the second upper magnetized pinned layer 184, where the first upper magnetized pinned layer 182 and the second upper magnetized pinned layer 184 constitute an SAF structure in the upper magnetized pinned layer 180, an Hc shift of the magnetized free layer 164 may be prevented and a switching characteristic may be improved.

In order to optimize Hc of the lower magnetized pinned layer 130, the lower magnetized pinned layer 130 may be formed of a superlattice having an L1₁ type ordered structure. In particular, in order to form the lower magnetized pinned layer 130 by using a superlattice with long-range order, which provides high perpendicular anisotropy and improved coercivity, the buffer layer 114 and the seed layer 120 of which a crystalline axis is controlled by the buffer layer 114 are in turn formed between the electrode 110 and the lower magnetized pinned layer 130. In this manner, by forming the lower magnetized pinned layer 130, which is formed of the L1₁ type superlattice layer, on the seed layer 120 where the buffer layer 114 and the seed layer 120 are sequentially formed and thus a vertical orientation property of the seed layer 120 has been increased due to the buffer layer 114, Hc of the lower magnetized pinned layer 130 may be in the range between Hc of the first upper magnetized pinned layer 182 and Hc of the second upper magnetized pinned layer 184.

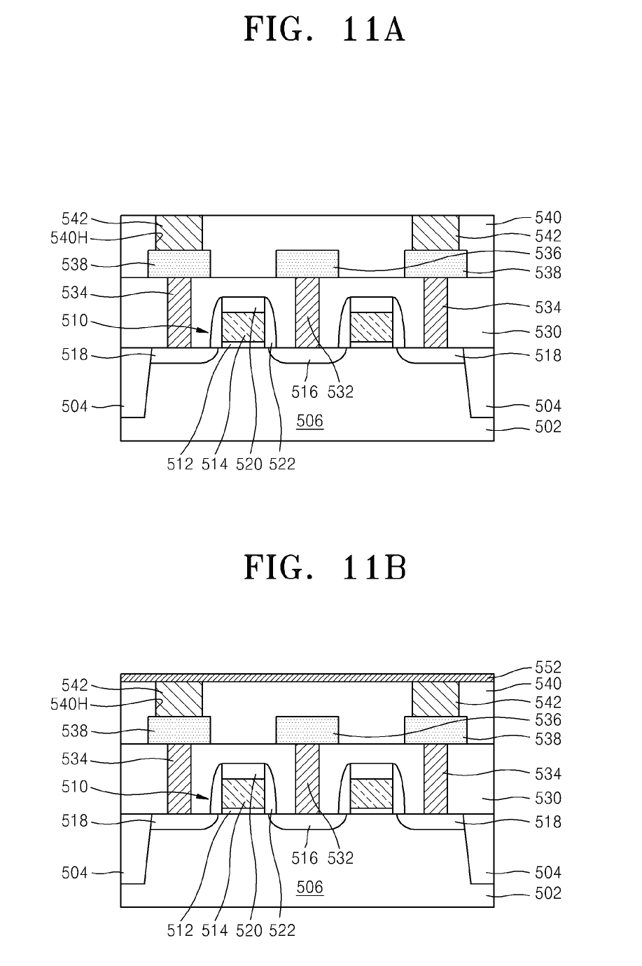

FIG. 7 is a graph for describing Hc distribution of the first upper magnetized pinned layer 182, Hc distribution of the second upper magnetized pinned layer 184, and Hc distribution of the lower magnetized pinned layer 130 in the magnetic device 100 illustrated in FIG. 4.

In FIG. 7, “PL1” indicates the Hc distribution of the first upper magnetized pinned layer 182, “PL2” indicates the Hc distribution of the second upper magnetized pinned layer 184, and “PL3” indicates the Hc distribution of the lower magnetized pinned layer 130. “FL” indicates Hc distribution of the magnetized free layer 164.

In the magnetic device 100, as the lower magnetized pinned layer 130 is formed of the L1₁ type superlattice layer having high perpendicular anisotropy, the Hc distribution of the lower magnetized pinned layer 130 is in the range between the Hc distribution of the first upper magnetized pinned layer 182 and the Hc distribution of the second upper magnetized pinned layer 184. Accordingly, although a stray field exists in the upper magnetized pinned layer 180 having the SAF structure, the stray field of the upper magnetized pinned layer 180 may be cancelled by that of the lower magnetized pinned layer 130. In addition, as illustrated in FIG. 7, the Hc distribution of the magnetized free layer 164 may be located in the range of an admissible read margin, and thus, a switching characteristic may be improved.

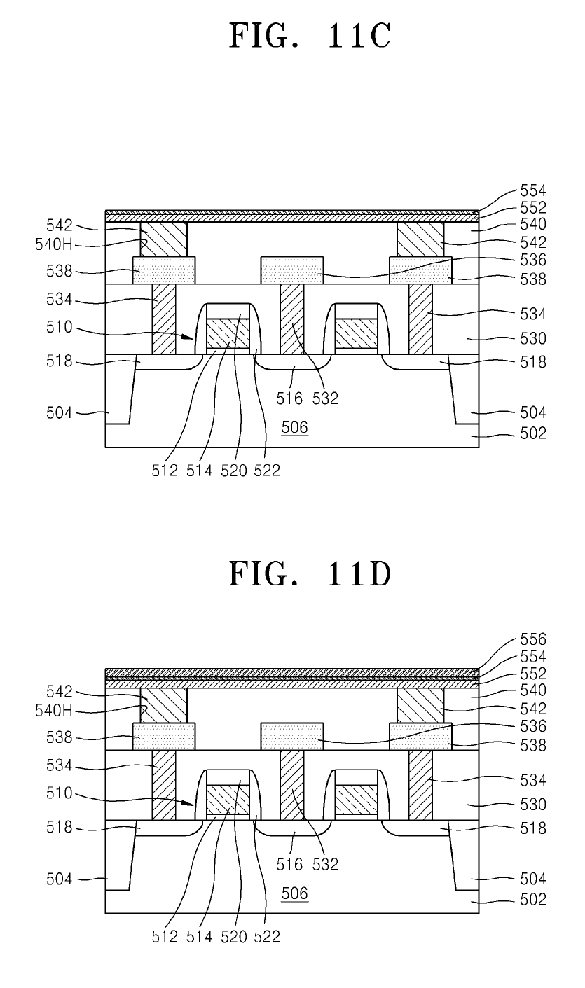

FIG. 8 is a cross-sectional view illustrating a magnetic device 200 according to an embodiment of the inventive concept. Like reference numerals in FIG. 8 and FIG. 4 refer to like elements, and thus, repeated descriptions thereof are omitted.

The magnetic device 200 has substantially the same configuration as the magnetic device 100 illustrated in FIG. 4. However, the magnetic device 200 further includes a first amorphous Ta film 234 interposed between the lower magnetized pinned layer 130 and the first polarization enhanced layer 150 and a second amorphous Ta film 274 interposed between the second polarization enhanced layer 172 and the first upper magnetized pinned layer 182. The first amorphous Ta film 234 and the second amorphous Ta film 274 each have a thickness in the range of about 2 Å to about 6 Å.

In the magnetic device 200 according to some embodiments, the first amorphous Ta film 234, the first polarization enhanced layer 150, the first tunnel barrier 160, the magnetized free layer 164, the second tunnel barrier 170, the second polarization enhanced layer 172, the second amorphous Ta film 274, and the first upper magnetized pinned layer 182 are formed as a Ta/CoFeB/MgO/CoFeB/MgO/CoFeB/Ta stack structure. Thus, a relatively high tunnel magnetoresistance ratio (TMR) may be obtained, excellent thermal stability may be obtained also in the case where a magnetic body stack structure of the magnetic device 200 has a minute line width of 20 nm or less, and a switching current may be lowered.

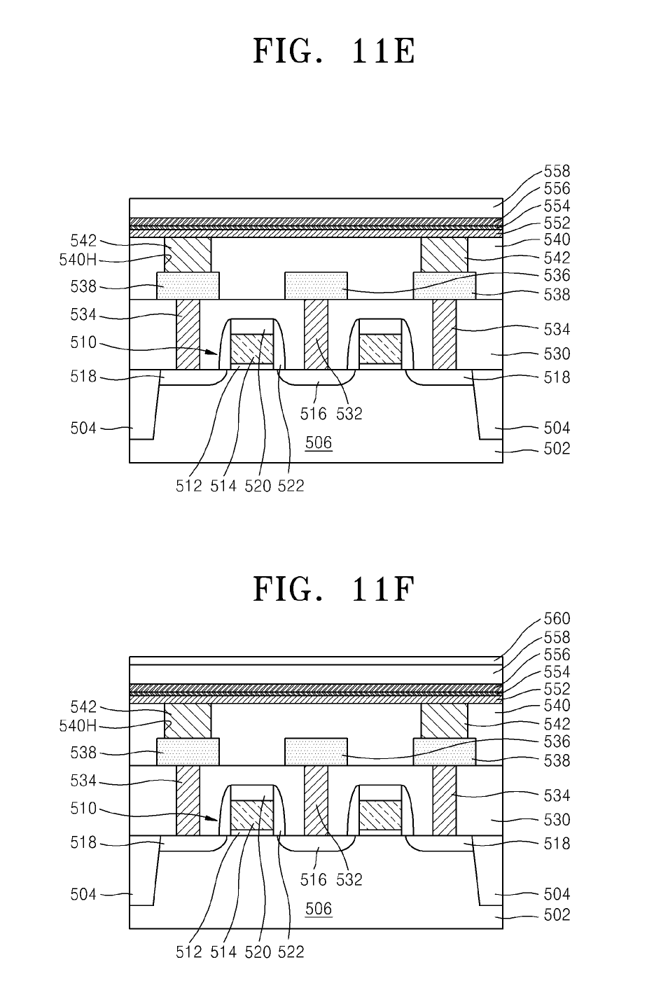

FIG. 9 is a cross-sectional view illustrating a magnetic device 300 according to another embodiment of the inventive concept. Like reference numerals in FIG. 9 and FIG. 4 refer to like elements, and thus, repeated descriptions thereof are omitted for the sake of simplicity.

The magnetic device 300 includes the electrode 110, the buffer layer 114, and the seed layer 120, which are sequentially stacked as described with reference to FIG. 4. The lower magnetized pinned layer 130 having perpendicular magnetic anisotropy is formed on the seed layer 120. In some embodiments, the lower magnetized pinned layer 130 may be formed of a superlattice with long-range order, which has an L1₁ type ordered structure.

An interchange combination film 340 and an upper magnetized pinned layer 350 are sequentially formed on the lower magnetized pinned layer 130. The upper magnetized pinned layer 350 has a magnetic moment antiparallel to that of the lower magnetized pinned layer 130. A more detailed configuration of the upper magnetized pinned layer 350 is the same as that of the second upper magnetized pinned layer 184 described with reference to FIG. 4.

A polarization enhanced layer 360, a tunnel barrier 370, a magnetized free layer 380, a nano-oxide layer (NOL) 382, and a capping layer 390 are sequentially formed on the upper magnetized pinned layer 350.

The polarization enhanced layer 360 may be formed of a CoFeB magnetic layer. The tunnel barrier 370 may include a non-magnetic material. The tunnel bather 370 and the magnetized free layer 380 are substantially the same as the second tunnel barrier 170 and the magnetized free layer 164, respectively, described with reference to FIG. 4.

The NOL 382 may be formed of a Ta oxide or an Mg oxide. necessary?

A detailed configuration of the capping layer 390 is substantially the same as that of the capping layer 190 described with reference to FIG. 4.

In the stack structure of the magnetic device 300 illustrated in FIG. 9, by forming the lower magnetized pinned layer 130, which may be formed of an L1₁ type superlattice layer having high perpendicular anisotropy, on the seed layer 120 where a vertical orientation property of the seed layer 120 has been increased due to the buffer layer 114, the magnetic device 300 may provide high spin polarization and thus may provide an improved switching characteristic.

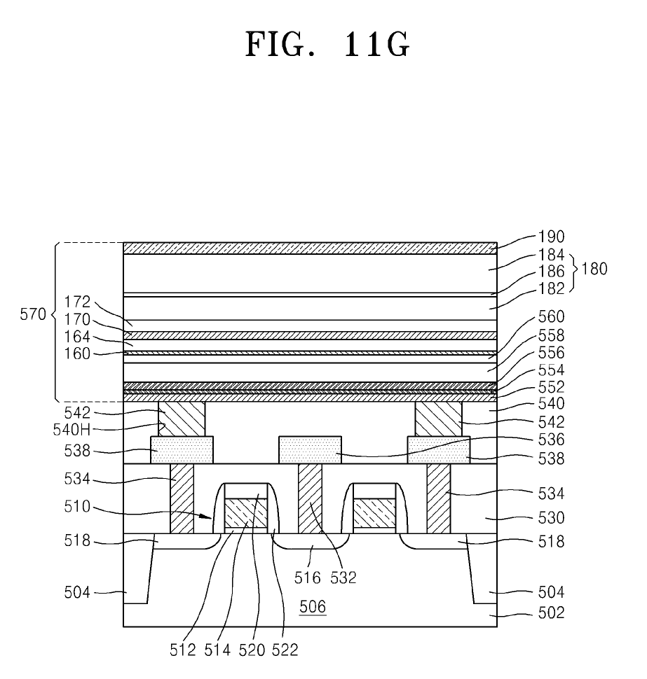

FIG. 10 is a flowchart illustrating, according to a process sequence, a method of manufacturing a magnetic device, according to an embodiment of the inventive concept.

Referring to FIG. 4 and FIG. 10, in process 410, the buffer layer 114 for controlling a crystalline axis of the seed layer 120 is formed on the electrode 110. The buffer layer 114 may have an HCP (0001) crystal structure or an amorphous structure. In some embodiments, the buffer layer 114 may be formed of a thin film having an HCP (0001) crystal structure. The buffer layer 114 having the HCP (0001) crystal structure may be formed of a material chosen from Ti, Zr, Hf, Y, Sc, and Mg. In some other embodiments, the buffer layer 114 may be formed of a thin film having an amorphous structure. The buffer layer 114 having the amorphous structure may be formed of at least one alloy chosen from among CoZr, CoHf, and CoFeBTa.

In some embodiments, a process of forming the buffer layer 114 may be performed under a temperature of about 10° C. to about 50° C. For example, the buffer layer 114 may be formed at room temperature. The buffer layer 114 may be formed by using a CVD, PVD, ALD, or reactive PLD process. In some embodiments, the buffer layer 114 may be formed by using a DC magnetron sputtering process using Kr as a sputtering gas. The buffer layer 114 may have a thickness in the range of about 0.1 nm to about 1.5 nm.

In process 420, the seed layer 120 having an HCP (0001) crystal structure is formed on the buffer layer 114.

Since the seed layer 120 having an HCP (0001) crystal structure is formed on the buffer layer 114 having an HCP (0001) crystal structure or an amorphous structure, a vertical orientation property may be improved due to the buffer layer 114. Accordingly, the seed layer 120 having a high vertical orientation property may be performed.

In some embodiments, the seed layer 120 may be formed of Ru. A process of forming the seed layer 120 is performed at a temperature range of about 10° C. to about 50° C. For example, the seed layer 120 may be formed at room temperature. The buffer layer 114 may be formed by using a CVD, PVD, ALD, or reactive PLD process. In some embodiments, the seed layer 120 may be formed by using a DC magnetron sputtering process using Kr as a sputtering gas. The seed layer 120 may have a thickness in the range of about 1 nm to about 10 nm. The thickness of the seed layer 120 may be larger than that of the buffer layer 114.

In process 430, the lower magnetized pinned layer 130 is formed on the seed layer 120.

Since a (0001) close-packed plane of the seed layer 120 has a matching property with respect to the growth of an fcc (111) close-packed plane of the lower magnetized pinned layer 130 having the L1₁ structure, a growth in a (111) plane may be faster when forming the lower magnetized pinned layer 130 on the seed layer 120 having the HCP (0001) structure. Accordingly, the lower magnetized pinned layer 130 that is formed of a superlattice with long-range order, which has an L1₁ type ordered structure, may be formed on the seed layer 120.

The lower magnetized pinned layer 130 may be formed by using an MBE process, a magnetron sputtering process, or a UHV sputtering process. The lower magnetized pinned layer 130 may have a thickness in the range of about 20 Å to about 30 Å.

A process of forming the lower magnetized pinned layer 130 may be performed at a temperature range of about 200° C. to about 400° C. Since the lower magnetized pinned layer 130 has excellent perpendicular anisotropy and may be formed at a relatively low temperature, the lower magnetized pinned layer 130 may be suitably applied to a magnetic device.

In some embodiments, the lower magnetized pinned layer 130 may be formed to have the aforementioned [Co/Pt]×n structure or [Co/Pd]×n structure (where n is the number of repeats). The lower magnetized pinned layer 130 may have a thickness in the range of about 20 Å to about 30 Å.

In process 440, the polarization enhanced layer 150 magnetized in a direction substantially perpendicular to the upper surface of the lower magnetized pinned layer 130 is formed on the lower magnetized pinned layer 130.

A process of forming the polarization enhanced layer 150 may include a process of forming a CoFeB magnetic layer. By forming the CoFeB magnetic layer that contacts the lower magnetized pinned layer 130 formed of an L1₁ type superlattice layer, the polarization enhanced layer 150 formed of the CoFeB magnetic layer that is vertically oriented may be formed. The magnetization direction of the polarization enhanced layer 150 may be the same as that of the lower magnetized pinned layer 130. The polarization enhanced layer 150 may have a thickness in the range of about 10 Å to about 20 Å.

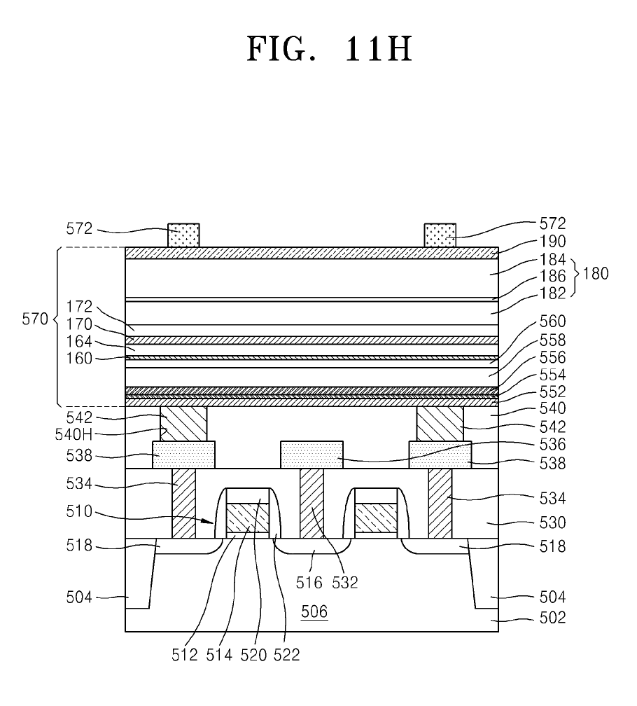

FIGS. 11A through 11K are cross-sectional views illustrating a method of manufacturing a magnetic device 500 (refer to FIG. 11K), according to an embodiment of the inventive concept. In the present embodiment, a process of manufacturing an STT-MRAM, including a stack structure of the magnetic device 100 illustrated in FIG. 4, is described. Like reference numerals in FIGS. 11A through 11K and FIG. 4 refer to like elements, and thus, repeated descriptions thereof are omitted for the sake of simplicity.

Referring to FIG. 11A, a device isolation film 504 is formed in a substrate 502 to define an active region 506, and a transistor 510 is formed on the active region 506.

In some embodiments, the substrate 502 may be a semiconductor wafer. The substrate 502 may include Si. In some other embodiments, the substrate 502 may include a semiconductor element such as Ge, or a compound semiconductor such as SiC, GaAs, InAs, and InP. In some other embodiments, the substrate 502 may have a silicon-on-insulator (SOI) structure. For example, the substrate 502 may include a buried oxide (BOX) layer. In some embodiments, the substrate 502 may include a conductivity region, for example, a well doped with impurities, or a structure doped with impurities. The device isolation film 504 may have a shallow trench isolation (STI) structure.

The transistor 510 may include a gate insulating film 512, a gate electrode 514, a source region 516, and a drain region 518. The gate electrode 514 has an insulating capping pattern 520 formed thereon and has facing side walls respectively insulated by insulating spacers 522.

Thereafter, a first interlayer insulating film 530 is formed on the substrate 502 to cover the transistor 510, and a first contact plug 532 that is electrically connected to the source region 516 through the first interlayer insulating film 530 and a second contact plug 534 that is electrically connected to the drain region 518 through the first interlayer insulating film 530 are formed. Then, the first interlayer insulating film 530 may be planarized. A conductive layer is formed on the first interlayer insulating film 530, and then, the conductive layer is patterned to form a source line 536 electrically connected to the source region 516 through the first contact plug 532, and to form conductive patterns 538 that are spaced from each other with the source line 536 therebetween and are electrically connected to drain regions 518 through second contact plugs 534.

Then, a second interlayer insulating film 540 is formed on the first interlayer insulating film 530 to cover the source line 536 and the conductive patterns 538. By using a photolithography process, portions of the second interlayer insulating film 540 are removed to form lower electrode contact holes 540H exposing top surfaces of the conductive patterns 538. The lower electrode contact holes 540H are filled with a conductive material, and the conductive material is polished or planarized until a top surface of the second interlayer insulating film 540 is exposed to form lower electrode contact plugs 542. In some embodiments, the lower electrode contact plugs 542 may include at least one material chosen from TiN, Ti, TaN, Ta, and W.

Referring to FIG. 11B, a lower electrode layer 552 is formed on the second interlayer insulating film 540 and the lower electrode contact plugs 542.

In some embodiments, the lower electrode layer 552 is formed of a metal or a metal nitride. For example, the lower electrode layer 552 may be formed of TiN. More detailed descriptions of the lower electrode layer 552 are the same as those of the electrode 110 described with reference to FIG. 4.

Referring to FIG. 11C, a buffer layer 554 is formed on the lower electrode layer 552.

The buffer layer 554 is formed to control a direction of a crystalline axis of a seed layer 556 (refer to FIG. 11D) to be sequentially formed on the buffer layer 554. The buffer layer 554 may be formed of a material having an HCP (0001) crystal structure, for example, at least one material chosen from Ti, Zr, Hf, Y, Sc, and Mg. Alternatively, the buffer layer 554 may be formed of a material having an amorphous structure, for example, at least one alloy selected from among CoZr, CoHf, and CoFeBTa.

The buffer layer 554 may be formed at room temperature. More detailed descriptions of the buffer layer 554 are the same as those of the buffer layer 114 described with reference to FIG. 4.

Referring to FIG. 11D, the seed layer 556 is formed on the buffer layer 554.

The seed layer 556 may be formed of a material having an HCP (0001) crystal structure. For example, the seed layer 556 may include a Ru layer.

By forming the seed layer 556 on the buffer layer 554 formed of a material having an HCP (0001) crystal structure or an amorphous structure, a vertical orientation property of the seed layer 556 may be improved. A more detailed configuration of the seed layer 556 is substantially the same as that of the seed layer 120 described with reference to FIG. 4.

Referring to FIG. 11E, a lower magnetized pinned layer 558 is formed on the seed layer 556.

The lower magnetized pinned layer 558 is formed to have a magnetization easy axis in a direction substantially perpendicular to a surface of the seed layer 556.

The lower magnetized pinned layer 558 may be formed of a superlattice having an L1₁ structure. In some embodiments, the lower magnetized pinned layer 558 may have a structure of [Co/Pt]×n (where n is the number of repeats) in which a Co film having a thickness in the range of about 1 Å to about 2 Å and a Pt film having a thickness in the range of about 1 Å to about 2 Å are stacked alternately and repeatedly. In some other embodiments, the lower magnetized pinned layer 558 may have a structure of [Co/Pd]×n (where n is the number of repeats) in which a Co film having a thickness in the range of about 1 Å to about 2 Å and a Pd film having a thickness in the range of about 1 Å to about 2 Å are alternately stacked multiple times. In this case, “n” may be an integer in the range of 2 to 20.

The lower magnetized pinned layer 558 may be formed by using an MBE process or an MOCVD process. The lower magnetized pinned layer 558 may be formed under a relatively low process temperature in the range of about 200° C. to about 400° C. For example, the lower magnetized pinned layer 558 may be formed at about 300° C. The lower magnetized pinned layer 558 may have a thickness in the range of about 20 Å to about 30 Å.

A more detailed configuration of the lower magnetized pinned layer 558 is substantially the same as that of the lower magnetized pinned layer 130 described with reference to FIG. 4.

Referring to FIG. 11F, a first polarization enhanced layer 560 may be formed on the lower magnetized pinned layer 558.

The first polarization enhanced layer 560 may be formed of a CoFeB magnetic layer. When forming the first polarization enhanced layer 560, because a CoFeB magnetic layer is formed on the lower magnetized pinned layer 558 formed of an L1₁ type superlattice layer to contact the lower magnetized pinned layer 558, a vertically oriented CoFeB magnetic layer may be obtained. High spin polarization may be provided by a combination of the lower magnetized pinned layer 558 and the first polarization enhanced layer 560. The first polarization enhanced layer 560 may have a thickness in the range of about 10 Å to about 20 Å. A more detailed configuration of the first polarization enhanced layer 560 is the same as that of the first polarization enhanced layer 150 described with reference to FIG. 4.

Referring to FIG. 11G, a first tunnel barrier 160, a free layer 164, a second tunnel barrier 170, a second polarization enhanced layer 172, an upper magnetized pinned layer 180, and a capping layer 190 are sequentially formed on the first polarization enhanced layer 560. The upper magnetized pinned layer 180 includes a first upper magnetized pinned layer 182, a second upper magnetized pinned layer 184, and an interchange combination film 186 interposed between the first upper magnetized pinned layer 182 and the second upper magnetized pinned layer 184.

The capping layer 190 may include at least one material chosen from Ta, Al, Cu, Au, Ti, TaN, and TiN.

FIG. 11G illustrates the case where layers (from the lower electrode layer 552 to the capping layer 190) of a stack structure 570 are stacked in the same order as the stack structure of the magnetic device 100 of FIG. 4. However, the inventive concept is not limited thereto. For example, instead of the stack structure 570, a stack structure in which layers are stacked in the same order as the magnetic device 200 illustrated in FIG. 8 or a stack structure in which layers are stacked in the same order as the magnetic device 300 illustrated in FIG. 9 may be formed. According to some embodiments of the inventive concept, various kinds of layers may be added or replaced in the stack structure 570 according to a desired characteristic of a magnetic device to be formed.

Referring to FIG. 11H, a plurality of conductive mask patterns 572 are formed on the stack structure 570.

The plurality of conductive mask patterns 572 may be formed of a metal or a metal nitride. In some embodiments, the plurality of conductive mask patterns 572 include at least one material selected from among Ru, W, TiN, TaN, Ti, Ta, and a metallic glass alloy. For example, the conductive mask patterns 572 may have a dual layer structure of Ru/TiN or TiN/W. The conductive mask patterns 572 are formed on the same axis as the lower electrode contact plug 542.

Referring to FIG. 11I, a portion of the stack structure 570 is etched by using the plurality of conductive mask patterns 572 as an etch mask.

The resulting structure including the plurality of conductive mask patterns 572 may be loaded into a plasma etch chamber. Then, a portion of the stack structure 570 may be etched by plasma etching. In some embodiments, a portion of the stack structure 570 may be etched by reactive ion etching (RIE), ion beam etching (IBE), or Ar milling. The stack structure 570 may be etched by using a first etch gas that includes SF₆, NF₃, SiF₄, CF₄, Cl₂, CH₃OH, CH₄, CO, NH₃, H₂, N₂, HBr, or a combination thereof. In some other embodiments, during the etching of the stack structure 570, at least one first additional gas from Ne, Ar, Kr, and Xe may be further used in addition to the first etch gas.

An etch process for etching the stack structure 570 may be performed by using plasma generated from an inductively coupled plasma (ICP) source, a capacitively coupled plasma (CCP) source, an electron cyclotron resonance (ECR) plasma source, a helicon-wave excited plasma source, or an adaptively coupled plasma (ACP) source.

An etch process for etching the stack structure 570 may further include an etch process using a second etch gas having a composition that is different from that of the first etch gas. The second etch gas may include SF₆, NF₃, SiF₄, CF₄, Cl₂, CH₃OH, CH₄, CO, NH₃, H₂, N₂, HBr, or a combination thereof. In some other embodiments, during the etch process using the second etch gas, at least one second additional gas selected from among Ne, Ar, Kr, and Xe may be further used.

The etch process for etching the stack structure 570 may be performed at a temperature range of about −10 to about 65° C., and at a pressure of about 2 to about 5 mT. During the etch process, the conductive mask patterns 572 may be consumed to have a reduced thickness from top surfaces of the conductive mask patterns 572 under the etch atmosphere of the etch process.

Although not illustrated, after a plurality of lower electrodes 552A were formed by etching the stack structure 570, an exposed second interlayer insulating film 540 may be etched by a predetermined thickness from a top surface thereof.

As a result, a plurality of magnetoresistance devices 570A, including a resultant structure remaining after etching the stack structure 570, are formed on the plurality of lower electrode contact plugs 542. In the plurality of magnetoresistance devices 570A, the remaining portion of the plurality of conductive mask patterns 572 and the capping layer 190 function as an upper electrode.

Referring to FIG. 11J, a third interlayer insulating film 580 may be formed to cover the magnetic resistance devices 570 and planarized. Portions of the third interlayer insulating film 580 are removed to expose top surfaces of the conductive mask patterns 572 of the magnetic resistance devices 570 by forming a plurality of bit line contact holes 580H. Thereafter, a conductive layer is formed to fill the bit line contact holes 580H, and then polishing or etch-back is performed thereon until a top surface of the third interlayer insulating film 580 is exposed, thereby forming a plurality of bit line contact plugs 582 in the bit line contact holes 580H, respectively.

Referring to FIG. 11K, a conductive layer is formed on the third interlayer insulating film 580 and the bit line contact plugs 582, followed by patterning to form a bit line 590 electrically connected to the bit line contact plugs 582, thereby completing the manufacture of the magnetic device 500. The bit line 590 may have a line shape.

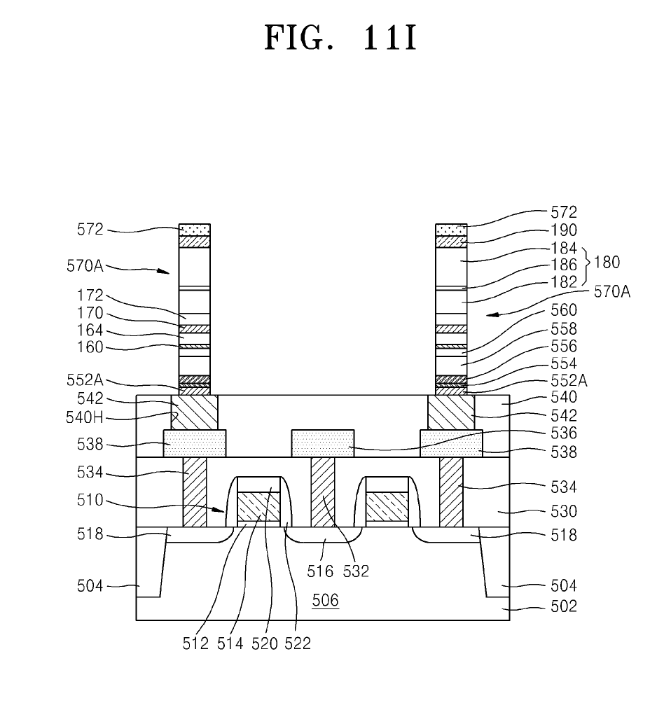

FIG. 12 is a graph illustrating a magnetization hysteresis (M-H) loop of a magnetic device according to an embodiment of the inventive concept.

To evaluate the M-H loop of FIG. 12, a magnetic device having a stack structure that is substantially the same as that of the magnetic device 200 illustrated in FIG. 8 was manufactured. In more detail, a Ti buffer layer having a thickness of 10 Å, a Ru seed layer having a thickness of 50 Å, a lower magnetized pinned layer including an L1₁ type [Co (2)/Pt (2)]×7 superlattice layer (numerals in parentheses indicate thickness and the unit of thickness is Å), a first amorphous Ta film having a thickness of 4 Å, and a first CoFeB polarization enhanced layer having a thickness of 8 Å were sequentially formed on a TiN electrode. In this case, the Ti buffer layer and the Ru seed layer were formed at room temperature, and the lower magnetized pinned layer were formed at a temperature of about 300° C.

Then, the magnetic device having a stack structure that includes a first tunnel barrier including a MgO film, a CoFeB magnetized free layer having a thickness of 12 Å, a second tunnel barrier including a MgO film having resistance that is about ten times larger than that of the first tunnel barrier, a second amorphous Ta film having a thickness of 4 Å, and an upper magnetized pinned layer having an SAF structure of [Co (2.5)/Pd (10)]×3/Ru/[Co (2.5)/Pd (10)]×3 was manufactured.

When forming the Ru seed layer on the Ti buffer layer and then forming the lower magnetized pinned layer including a Co/Pt superlattice layer with an L1₁ structure on the Ru seed layer, the Co/Pt superlattice layer with the L1₁ structure is formed with a long-range order structure along an out-of-plane axis of the grains of Ru constituting the Ru seed layer. Thus, an effect of increasing out-of-plane perpendicular anisotropy is provided as a twisted axis of a vertical surface prevents the movement of a domain wall according to the grains. Accordingly, as shown in FIG. 12, an ideal M-H loop in which magnetization reversal rapidly occurs is obtained.

In particular, referring to FIG. 12, it is shown that coercivity of the magnetic device increases to about 4000 Oersteds (Oe). This is due to forming the lower magnetized pinned layer including the Co/Pt superlattice layer with the L1₁ structure on the Ti buffer layer and Ru seed layer.

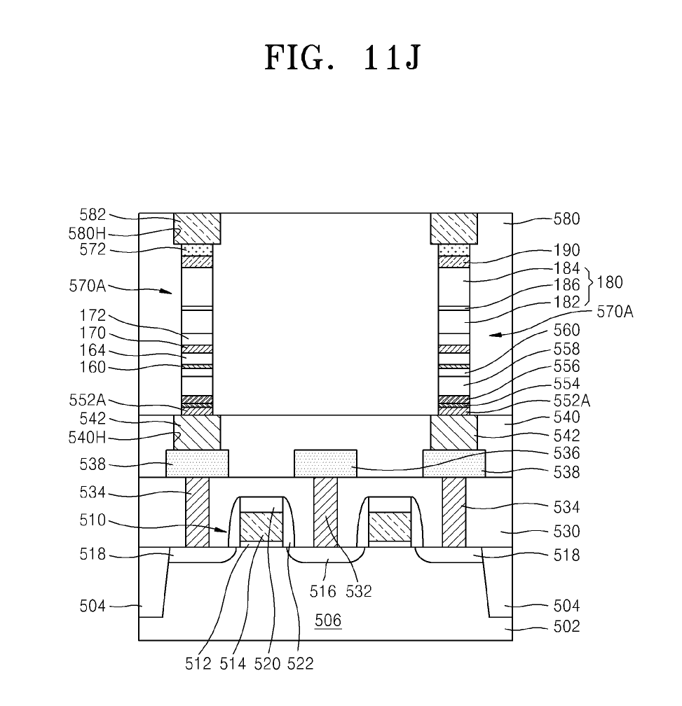

FIG. 13 is a graph illustrating another M-H loop for comparison.

To evaluate the M-H loop of FIG. 13, a magnetic device for comparison was manufactured in the same conditions used to evaluate the M-H loop of FIG. 12, except that a Ta layer was formed instead of the Ti buffer layer.

In the magnetic device for comparison, when growing a Ta layer on a TiN electrode, Ta is crystallized from an amorphous structure to a body centered cubic lattice (BCC) crystal structure. Accordingly, when forming a Ru seed layer on the Ta layer, a matching between the Ta layer having a BCC crystal structure and the Ru seed layer having an HCP crystal structure is broken, thereby deteriorating crystallization of the Ru seed layer. As a result, a crystalline axis of the Co/Pt superlattice layer with the L1₁ structure, which is formed on the Ru seed layer, is twisted and a long-range order of the Co/Pt superlattice layer is broken, and thus, a perpendicular magnetic characteristic is deteriorated as shown in FIG. 13.

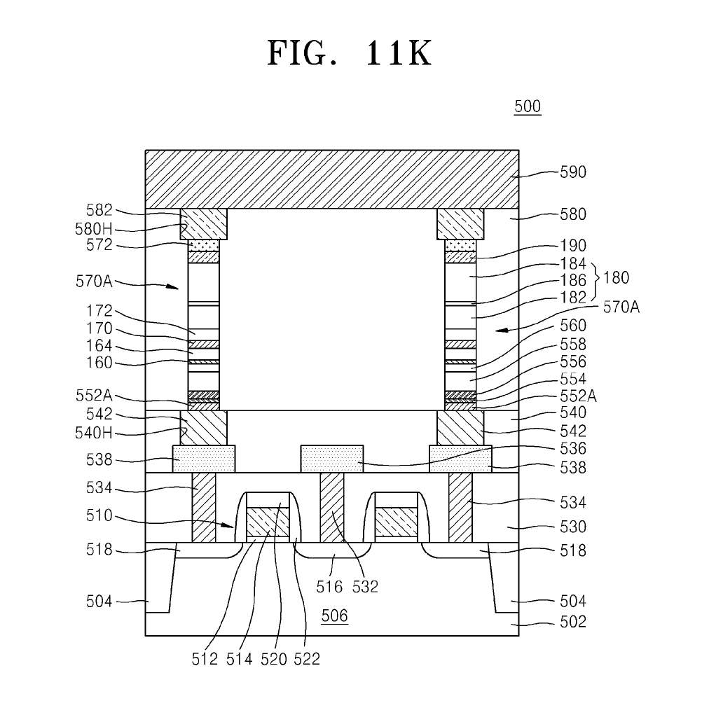

FIG. 14 is a graph illustrating magnetic moment characteristics according to a magnetic field applied from the outside, in a magnetic device according to some embodiments of the inventive concept.

To evaluate the magnetic moment characteristics of FIG. 14, a magnetic device for comparison was manufactured under the same conditions used to evaluate the M-H loop of FIG. 12, except that a first polarization enhanced layer including a Co_{0.2}Fe_{0.6}B_{0.2} magnetic layer was formed and the thickness of the first polarization enhanced layer was variously changed.

In FIG. 14, “A” (CFB 12 Å) indicates a case where a CoFeB magnetic layer having a thickness of 12 Å was formed as the first polarization enhanced layer. “B” (CFB 14.5 Å) indicates a case where a CoFeB magnetic layer having a thickness of 14.5 Å was formed as the first polarization enhanced layer. “C” (CFB 17.1 Å) indicates a case where a CoFeB magnetic layer having a thickness of 17.1 Å was formed as the first polarization enhanced layer.

Referring to FIG. 14, it is shown that the CoFeB magnetic layer has perpendicular magnetic anisotropy to a thickness of about 17 Å.

In the magnetic device, the larger the thickness of a CoFeB magnetic layer having perpendicular magnetic anisotropy, the more spin polarization increases since a first MgO tunnel barrier is grown to have a BCC structure when the first MgO tunnel barrier is contact with and formed on the CoFeB magnetic layer.

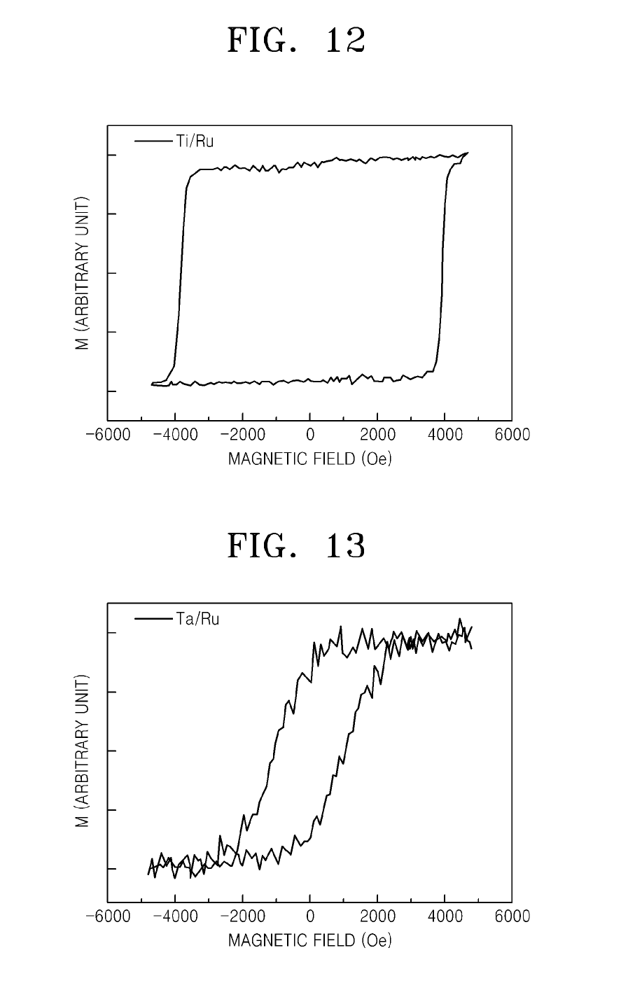

FIG. 15 is a block diagram of an electronic system 700 including a magnetic device according to an embodiment of the inventive concept.

Referring to FIG. 15, the electronic system 700 includes an input device 710, an output device 720, a processor 730, and a memory device 740. In some embodiments, the memory device 740 may include a cell array including a plurality of non-volatile memory cells and a peripheral circuit for operations, such as a read operation and a write operation. In some other embodiments, the memory device 740 may include a non-volatile memory device and a memory controller.

A memory 742 included in the memory device 740 may include a magnetic device according to the above embodiments of the inventive concept, which is described with reference to FIGS. 1 through 11K.

The processor 730 may be connected to the input device 710, the output device 720, and the memory device 740 through an interface to control the overall operation of the electronic system 700.

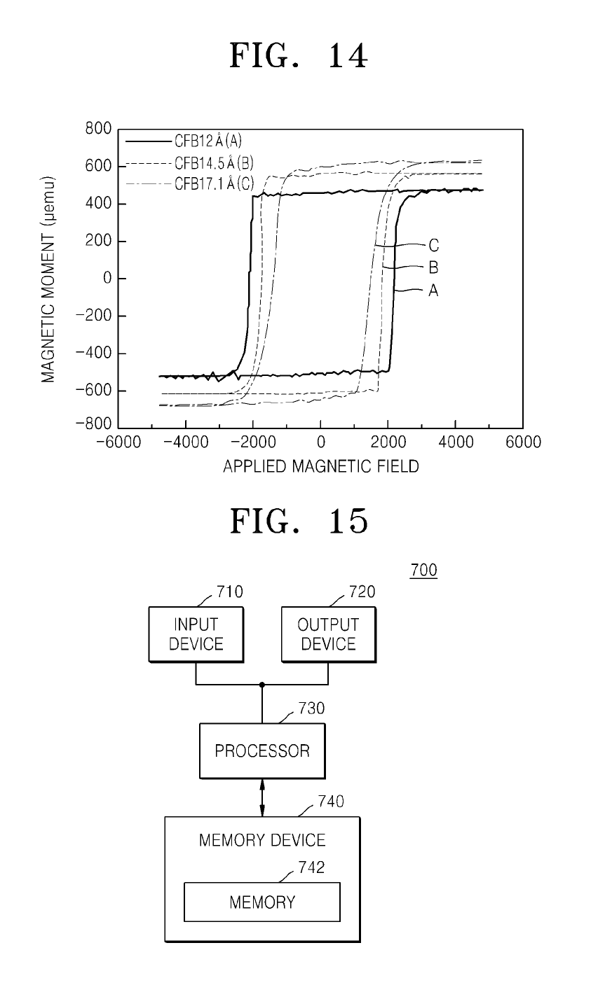

FIG. 16 is a block diagram of an information processing system 800 including a magnetic device according to an embodiment of the inventive concept.

Referring to FIG. 16, the information processing system 800 includes a non-volatile memory system 810, a modem 820, a central processing unit (CPU) 830, a random access memory (RAM) 840, and a user interface 850, which are electrically connected to a bus 802.

The non-volatile memory system 810 may include a memory 812 and a memory controller 814. The non-volatile memory system 810 stores data processed by the CPU 830 or data input from the outside.

The non-volatile memory system 810 may include a non-volatile memory such as an MRAM, a PRAM, an RRAM, a FRAM, etc. At least one of the memory 812 and the RAM 840 may include a magnetic device according to one of the above embodiments of the inventive concept, which is described with reference to FIGS. 1 through 11K.

The information processing system 800 may be applied to a portable computer, a web tablet, a wireless phone, a mobile phone, a digital music player, a memory card, an MP3 player, a navigation system, a portable multimedia player (PMP), a solid state disk (SSD), or household appliances.

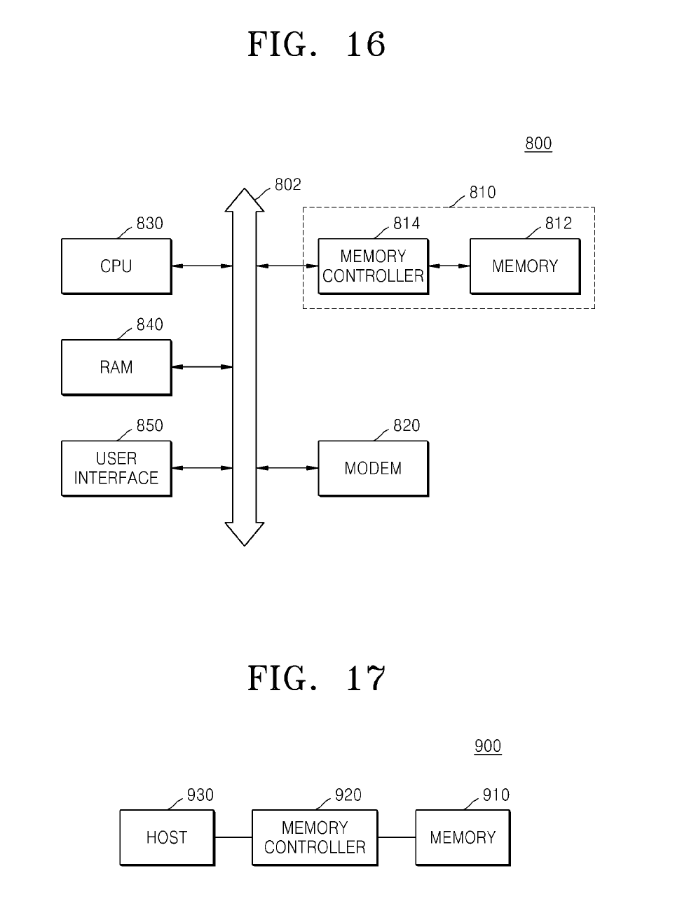

FIG. 17 is a block diagram of a memory card 900 including a magnetic device according to an embodiment of the inventive concept.

The memory card 900 includes a memory 910 and a memory controller 920.

The memory 910 may store data. In some embodiments, the memory 910 may have a non-volatile characteristic that data is maintained even when a power supply is stopped. The memory 910 may include a magnetic device according to one of the above embodiments of the inventive concept, which is described with reference to FIGS. 1 through 11K.

The memory controller 920 may read data stored in the memory 910 or may store data in the memory 910 in response to a read/write request of a host 930.

While the inventive concept has been particularly shown and described with reference to exemplary embodiments thereof, it will be understood that various changes in form and details may be made therein without departing from the spirit and scope of the following claims.

1. A magnetic device comprising:
a magnetoresistance device and lower and upper electrodes with the magnetoresistance device interposed therebetween,
wherein the magnetoresistance device comprises:
a buffer layer for controlling a crystalline axis for inducing perpendicular magnetic anisotropy (PMA) in the magnetoresistance device, the buffer layer in contact with the lower electrode;
a seed layer in contact with the buffer layer and oriented to have a hexagonal close-packed lattice (HCP) (0001) crystal plane; and
a perpendicularly magnetized pinned layer in contact with the seed layer and having an L1₁ type ordered structure.

2. The magnetic device of claim 1, wherein the buffer layer comprises Ti, Zr, Hf, Y, Sc, Mg, CoZr, CoHf, or CoFeBTa.

3. A magnetic device comprising:
an electrode;
a buffer layer formed on the electrode;
a seed layer formed on the buffer layer;
a first magnetized layer formed on the seed layer;
a first tunnel barrier formed on the first magnetized layer;
a second magnetized layer formed on the first tunnel barrier; and
a third magnetized layer formed on the second magnetized layer and having a synthetic antiferromagnetic coupling (SAF) structure.

4. The magnetic device of claim 3, wherein the buffer layer and the seed layer comprise the same crystal structure.

5. The magnetic device of claim 3, wherein the buffer layer and the seed layer each comprise a hexagonal close-packed lattice (HCP) (0001) crystal structure.

6. The magnetic device of claim 5, wherein the electrode comprises an HCP crystal structure.

7. The magnetic device of claim 3, wherein the buffer layer comprises at least one of Ti, Zr, Hf, Y, Sc, or Mg.

8. The magnetic device of claim 3, wherein the buffer layer comprises an amorphous layer and the seed layer comprises an HCP (0001) crystal structure.

9. The magnetic device of claim 3, wherein the buffer layer comprises an alloy comprising Co.

10. The magnetic device of claim 9, wherein the buffer layer comprises a thin film that comprises CoZr, CoHf, or CoFeBTa.

11. The magnetic device of claim 3, wherein the buffer layer has a thickness in the range of about 0.1 nm to about 1.5 nm.

12. The magnetic device of claim 3, wherein the first magnetized layer comprises a magnetic material having an L1₁ type ordered structure.

13. The magnetic device of claim 12, wherein the first magnetized layer comprises a perpendicularly magnetized layer in which a first layer comprising Co and a second layer comprising Pt or Pd are alternately formed.

14. The magnetic device of claim 3, wherein the first magnetized layer is a pinned layer and the second magnetized layer is a free layer.

15. The magnetic device of claim 3, further comprising a polarization enhanced layer disposed between the first magnetized layer and the first tunnel barrier and being magnetized in a direction substantially perpendicular to a surface contacting with the first tunnel barrier.

16. The magnetic device of claim 3, further comprising a second tunnel barrier interposed between the second magnetized layer and the third magnetized layer.

17. A magnetic device comprising:
an electrode;
a buffer layer for controlling a crystalline axis for inducing perpendicular magnetic anisotropy (PMA) in a magnetic resistance device, the buffer layer in contact with the electrode;
a seed layer in contact with the buffer layer, the seed layer having a hexagonal close-packed lattice (HCP) (0001) crystal plane;
a lower magnetized pinned layer in contact with the seed layer and having an L1₁ type ordered structure;
a tunnel barrier overlying the lower magnetized pinned layer; and
a free layer formed overlying the tunnel barrier.

18. The device of claim 17, further comprising:
another tunnel barrier formed on the free layer; and
a reference layer formed on the free layer and having a synthetic antiferromagnetic coupling (SAF) structure.

19. The device of claim 18, further comprising:
a first polarization enhanced layer between the lower magnetized pinned layer and the tunnel barrier layer; and
a second polarization enhanced layer between another tunnel barrier and the reference layer.

20. The device of claim 19, further comprising a first amorphous Ta film interposed between the lower magnetized pinned layer and the first polarization enhanced layer and a second amorphous Ta film interposed between the second polarization enhanced layer and the reference layer.

21. The device of claim 20, wherein the first amorphous Ta film and the second amorphous Ta film each have a thickness in the range of about 2 Å to about 6 Å.

22. The device of claim 17, further comprising an interchange combination film on the lower magnetized pinned layer and an upper magnetized pinned layer on the interchange combination film.

23-32. (canceled)
